(19) United States
(12) Patent Application Publication
(10) Pub. No.: US 2008/0060194 A1
(43) Pub. Date: Mar. 13, 2008

(54) METHOD FOR FABRICATING PASSIVE CIRCUIT IN CIRCUIT SUBSTRATE

(75) Inventor: Guo-Cheng Liao, Kaohsiung (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/830,167

(22) Filed: Jul. 30, 2007

(30) Foreign Application Priority Data
Sep. 13, 2006 (TW) 95133851

(51) Int. Cl. H05K 3/10; H01K 3/10; H05K 3/00; B05D 5/12

(52) U.S. Cl. 29/852; 427/97.9; 427/99.5; 29/831; 29/846

(57) ABSTRACT

A method for fabricating a passive circuit in a circuit substrate is provided. The circuit substrate comprising a first metallic layer, a second metallic layer, and a dielectric layer is provided firstly, and the dielectric layer is disposed between the first metallic layer and the second metallic layer. Thereafter, a strip shaped through hole through the circuit substrate is formed. Afterward, a third metallic layer is formed on a part of a wall of the strip shaped through hole, and the third metallic layer is electrically connected to the first metallic layer and/or the second metallic layer. The third metallic layer functions as the passive circuit.

### CROSS-REFERENCE TO RELATED APPLICATION

This application claims the priority benefit of Taiwan application serial no. 95133851, filed Sep. 13, 2006. All disclosure of the Taiwan application is incorporated herein by reference.

### BACKGROUND OF THE INVENTION

1. Field of the Invention

The present invention generally relates to a substrate and a method for fabricating a passive circuit therein, in particular, to a circuit substrate and a method for fabricating a passive circuit therein.

2. Description of Related Art

In the current highly informative days, the multimedia market is drastically expanding, in which integrated circuit (IC) packaging technology is also demanded for development in facilitation with the digitalization, network latticing, and local linkage, as well as friendly usability of electronic devices. Accordingly, electronic components are expected for high-speed possibility, multi-functionality, integration, slimness and lightness, and low production cost. As such, the IC packaging technology is being developed toward micromation and high density. However, after being packaged, an IC must be electrically connected to other IC packaging structures and active/passive components via a circuit substrate in which it is packaged for performing functions.

Typically, passive components are often packaged individually, and thereafter are weld or mounted to the circuit substrate by a surface mount technology (SMT). Unfortunately, such a process brings relative high production cost, as well as requirement for more time and labour for processing. Thus, as a solution, it is proposed to use an embedded passive component. An embedded capacitor is illustrated hereby as an example. In fabricating the circuit substrate, an upper electrode and a lower electrode are provided on two circuit layers for providing horizontally configured embedded capacitor in the circuit substrate. However, the embedded capacitor is suitable for providing only limited capacitance. Further, the horizontally configured capacitor occupies certain circuit space, and thus is not so practical.

### SUMMARY OF THE INVENTION

Accordingly, the present invention is directed to a method for fabricating a passive circuit in a circuit substrate, which is suitable for easily distributing a layout thereby.

The present invention provides a circuit substrate, which is adapted for improve utility of the passive circuit.

The present invention provides a method for fabricating a passive circuit in a circuit substrate. The method includes: providing a circuit substrate, the circuit substrate includes a first metallic layer, a second metallic layer, and a dielectric layer, the dielectric layer being disposed between the first metallic layer and the second metallic layer; forming a strip shaped through hole through the circuit substrate; forming a third metallic layer on a part of a wall of the strip shaped through hole, the third metallic layer being electrically connected to the first metallic layer and/or the second metallic layer, and the third metallic layer being a passive circuit.

According to an embodiment of the present invention of the method, the step of forming the third metallic layer includes: forming a plating seed layer on the entire wall of the strip shaped through hole, in which the plating seed layer is electrically connected to the first metallic layer and/or the second metallic layer; removing a part of the plating seed layer from the wall of the strip shaped through hole; and forming the third metallic layer by plating with the rest plating seed layer. Further, the step of forming a strip shaped through hole and the step of removing a part of the plating seed layer from the wall of the strip shaped through hole for example are conducted by using a same drill needle.

Further, the step of removing a part of the plating seed layer from the wall of the strip shaped through hole for example includes: removing the plating seed layer from the wall of an end of the strip shaped through hole. The step of removing a part of the plating seed layer from the wall of the strip shaped through hole may also includes: removing the plating seed layer from the wall of another end of the strip shaped through hole.

In an embodiment of the present invention, the step of forming the third metallic layer includes: forming a plating seed layer on an entire wall of the striped shaped through hole, the plating seed layer being electrically connected with the first metallic layer and/or the second metallic layer; forming a fourth metallic layer by a plating process with the plating seed layer; and removing a part of the fourth metallic layer and the plating seed layer from the wall of the strip shaped through hole so as to form the third metallic layer. Further, the step of forming a strip shaped through hole and the step of removing a part of the fourth metallic layer from the wall of the strip shaped through hole for example are conducted by using a same drill needle.

Furthermore, in an embodiment of the present invention, the step of removing a part of the fourth metallic layer from the wall of the strip shaped through hole for example for example includes: removing the fourth metallic layer from the wall of an end of the strip shaped through hole. Moreover, in another embodiment of the present invention, the step of removing a part of the fourth metallic layer from the wall of the strip shaped through hole may further include: removing the fourth metallic layer from the wall of another end of the strip shaped through hole.

According to an embodiment of the present invention, the method further includes filling a dielectric filling material into the strip shaped through hole after forming the third metallic layer.

According to an embodiment of the present invention, the method further includes patterning the first metallic layer and the second metallic layer, to form a first circuit layer and a second circuit layer, respectively.

The present invention further provides a circuit substrate, including: a first circuit layer, a second circuit layer, a dielectric layer and a metallic layer. The dielectric layer is disposed between the first circuit layer and the second circuit layer. The dielectric layer has a strip shaped through hole formed therethrough. The metallic layer, as a passive circuit, is disposed on a part of a wall of the strip shaped through hole, and is electrically connected to the first circuit layer and/or the second circuit layer.

According to an embodiment of the present invention, the metallic layer is a continuous metallic layer as an electric resistance circuit.

According to another embodiment of the present invention, the metallic layer includes a first electrode plate and a second electrode plate, electrically isolated from each other and forming a capacitance circuit thereby.

According to an embodiment of the present invention, the circuit substrate further includes a dielectric filling material filled in the strip shaped through hole.

According to an embodiment of the present invention, the strip shaped through hole is configured as a straight line form, an “S” form, or a sawtooth form.

In summary, the circuit substrate and the method for fabricating a passive circuit in the circuit substrate according to the present invention have the advantages of: compatible with the conventional process of fabricating circuit substrate, time saving, lower production cost, more practical, and requiring less layout space.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1 through 5 illustrate a method for fabricating a passive circuit in a circuit substrate according to an embodiment of the present invention.

FIGS. 6 are 7 are schematic diagrams illustrating optional steps after performing the method as illustrated in FIGS. 1 through 5.

FIG. 8 illustrates another alternative process of forming the third metallic layer of FIG. 5, and FIGS. 8 and 9 illustrate another alternative process of forming a fifth metallic layer of FIG. 6.

FIG. 10 is a perspective view illustrating a circuit substrate according to an embodiment of the present invention.

FIGS. 11 and 12 are top views of circuit substrates of another two embodiments of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

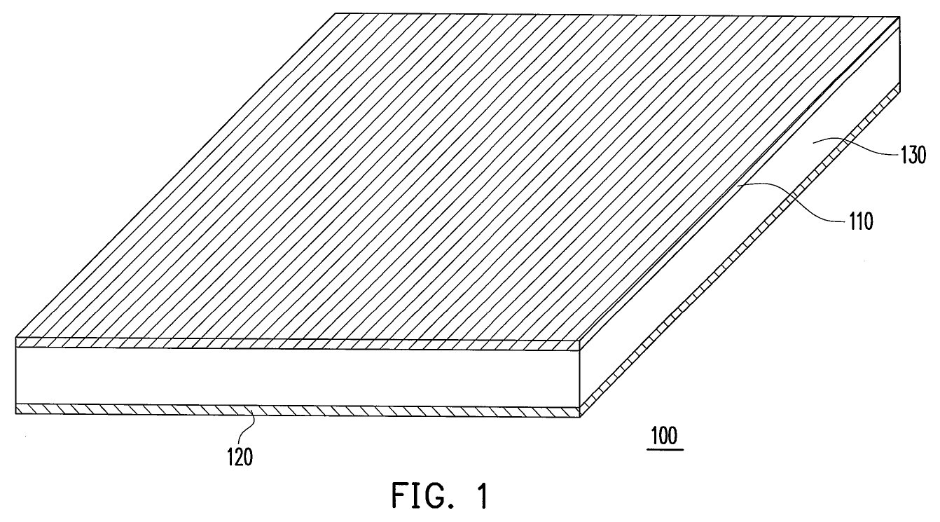

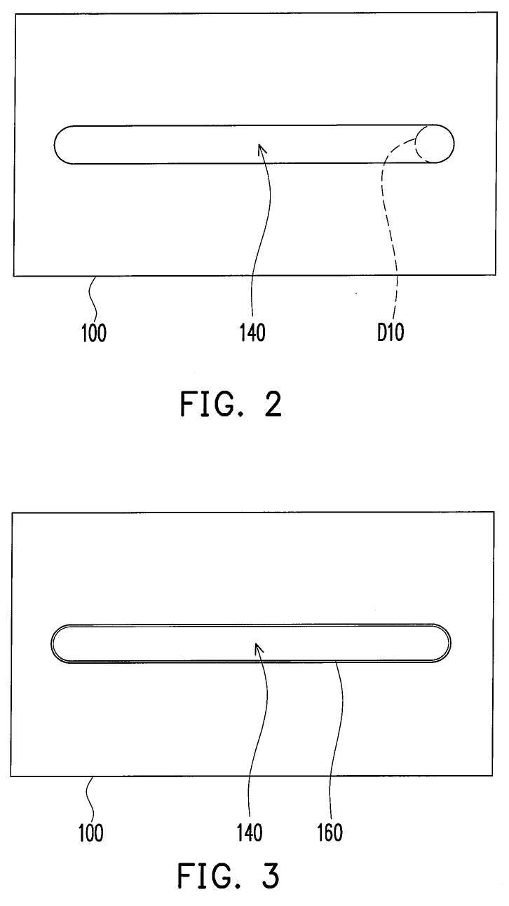

FIGS. 1 through 5 illustrate a method for fabricating a passive circuit in a circuit substrate according to an embodiment of the present invention, in which FIGS. 2 through 5 illustrate only one side of the circuit substrate.

Referring to FIG. 1, a first step of the embodiment is providing a circuit substrate 100. The circuit substrate 100 includes a first metallic layer 110, a second metallic layer 120 and a dielectric layer 130 disposed between the first metallic layer 110 and the second metallic layer 120. It should be noted that FIGS. 1 and 2 are given for illustration purpose only, and the scales of the first metallic layer 110, the second metallic layer 120 and the dielectric layer 130 exhibited therein do not represent factual proportion thereof. Further, although not shown in FIG. 1, the first metallic layer 110 and the second metallic layer 120 may have been patterned to be circuit layers having required circuit patterns formed thereon. Of course, the first metallic layer 110 and the second metallic layer 120 may also be patterned in another suitable alternative time.

Referring to FIG. 2, a strip shaped through hole 140 is formed though the circuit substrate 100 (only shown in FIG. 1). The strip shaped through hole 140 for example is formed by using a drill needle D10, illustrated by dashed circle in FIG. 2. However, the strip shaped through hole 140 may also be formed by other tools or processes, such as laser drilling.

Referring to FIG. 5, a third metallic layer 152 is then formed on a part of a wall of the strip shaped through hole 140. The third metallic layer 152 can be electrically connected with the first metallic layer 110 only, electrically connected with the second metallic layer 120 only, or electrically connected with both of the first metallic layer 110 and the second metallic layer 120. The third metallic layer 152 functions as a passive circuit. For example, the third metallic layer 152 can be a resistant circuit, a capacitance circuit, or other passive circuit.

The process of forming the third metallic layer 152 is illustrated as shown in FIGS. 3 through 5 according to the embodiment. Referring to FIG. 3, a plating seed layer 160 is formed on the entire wall of the strip shaped through hole 140. The plating seed layer 160 can be electrically connected with the first metallic layer 110 only, electrically connected with the second metallic layer 120 only, or electrically connected with both of the first metallic layer 110 and the second metallic layer 120. The plating seed layer 160 can be formed by electroless plating or other suitable approaches. The electrical connection or disconnection of the plating seed layer 160 to the first metallic layer 110 and/or the second metallic layer 120 can be determined according to for example whether the first metallic layer 110 and the second metallic layer 120 are distributed extensively to a boarder of the strip shaped through hole 140.

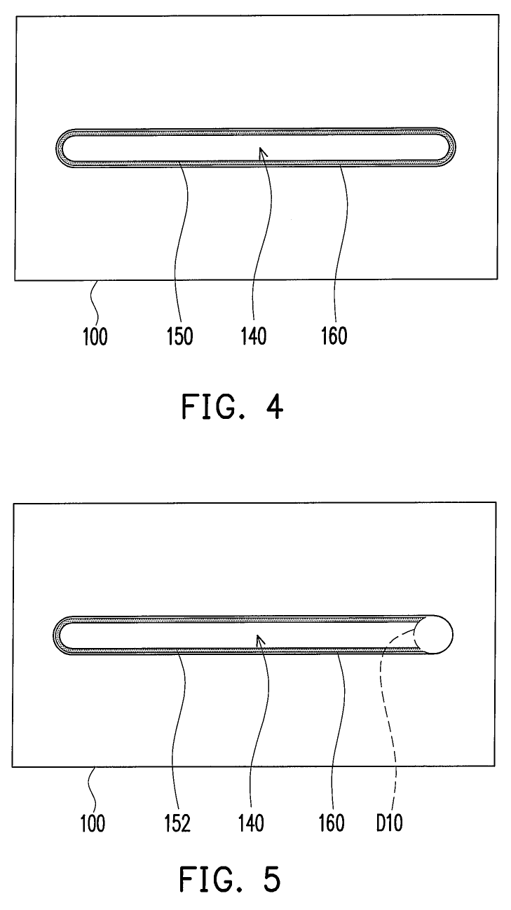

Referring to FIG. 4, a fourth metallic layer 150 is then formed on the entire wall of the strip shaped through hole 140 by a plating process with the plating seed layer 160.

Referring to FIG. 5, then the fourth metallic layer 150 on parts of the wall of the strip shaped through hole 140 and the plating seed layer 160, as shown in FIG. 4, are removed so as to form the third metallic layer 152. The step of removing a part of the fourth metallic layer 150 from the wall of the strip shaped through hole 140 for example is conducted by using the drill needle D10 or other tools, processes. If the drill needle D10 is used thereby, because the same drill needle D10, with its size unchanged, is also used for forming the strip shaped through hole 140, it is exactly suitable for removing a part of the fourth metallic layer 150 on the wall of the strip shaped through hole 140. In such a manner, production cost for equipment, e.g., drill needles, can also be saved. Of course, different drill needles D10 having different sizes from that forms the strip shaped through hole 140 may also be used for removing a part of the fourth metallic layer 150 on the wall of the strip shaped through hole 140 which is mostly concerned hereby in this step. In the embodiment, the third metallic layer 152 is formed by removing the fourth metallic layer 150 on the wall of an end of the strip shaped through hole 140. However, the removing operation is not limited to be conducted at an end of the through hole, and in other embodiments, it can also be conducted at a middle part of the strips shaped through hole 140.

In this way, the third metallic layer 152 is featured as a continuous metallic layer, having two ends both electrically connected to the first metallic layer 110, or both electrically connected to the second metallic layer 120, or electrically connected to the first metallic layer 110 and the second metallic layer 120, respectively. The third metallic layer 152 can be a resistant circuit or other passive circuit. The electrical connection or disconnection of the third metallic layer 152 to the first metallic layer 110 and/or the second metallic layer 120 can be determined according to for example whether the first metallic layer 110 and the second metallic layer 120 are distributed extensively to a boarder of the strip shaped through hole 140, or determined when selectively patterning the first metallic layer 110 and the second metallic layer 120.

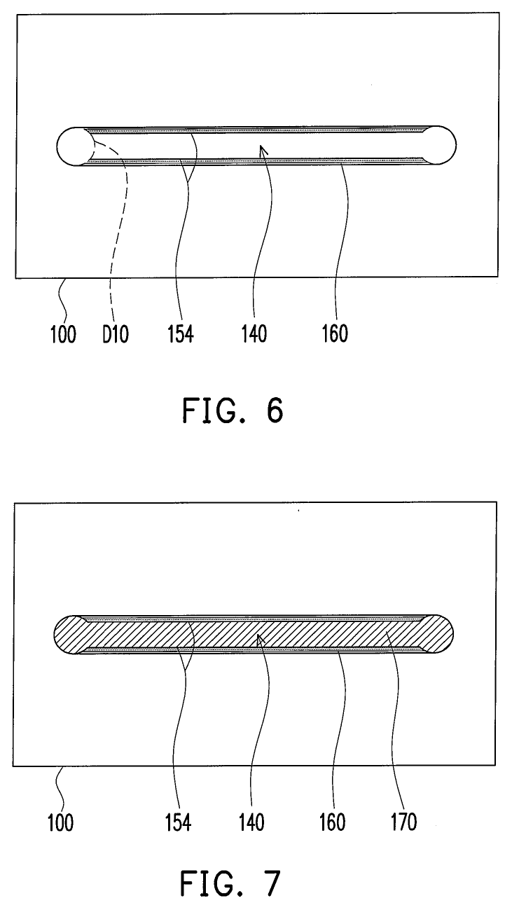

FIGS. 6 and 7 are schematic diagrams illustrating optional steps after performing the method as illustrated in FIGS. 1 through 5. Referring to FIG. 6, after forming the third metallic layer 152 as shown in FIG. 5, the method may further include a step of forming a fifth metallic layer 154 by removing the third metallic layer 154 on the wall of another end of the strip shaped through hole 140. This step may also be conducted by using the same drill needle D10, or other tools or processes. In such a manner, the fifth metallic layer 154 includes two portions isolated one from another, each of which having two ends both electrically connected to the first metallic layer 110, both electrically connected to the second metallic layer 120, or electrically connected to the first metallic layer 110 and the second metallic layer 120, respectively. The two portions of the fifth metallic layer are configured at two sides of the strip shaped through hole 140, respectively, and opposite one to another, so that the fifth metallic layer 154 can function as a capacitance circuit and store electric power therein. Further, the strip shaped through hole 140 can be processed to have an even and uniform width, so that a distance between the two portions of the fifth metallic layer 154 is uniform. As such, a top quality capacitance circuit can be obtained thereby. Furthermore, because the capacitance circuit constituted by the fifth metallic layer 154 is vertically configured in the circuit substrate 100, the area required thereby on the circuit substrate 100 is reduced. Therefore, the layout thereof can be handled relatively easy.

Referring to FIG. 7, after forming the fifth metallic layer 154 as shown in FIG. 6, the method may further include a step of: filling a dielectric filling material 170 into the strip shaped through hole 140. The dielectric filling material 170 for example is adapted for preventing the fifth metallic layer 154 from peeling off, and thus improving the reliability of the fifth metallic layer 154 as a passive circuit. Alternatively, the dielectric filling material 170 can also be filled into the strip shaped through hole 140 after forming the third metallic layer 152 as shown in FIG. 5.

Because the process of forming the strip shaped through hole 140 and the third metallic layer 152 or the fifth metallic layer 154 is compatible with the process of forming a typical conventional plating through hole (PTH), the method for fabricating a passive circuit in a circuit substrate according to the present invention is compatible with conventional processes of forming ordinary circuit substrate, and thus having advantages in saving production time and costs.

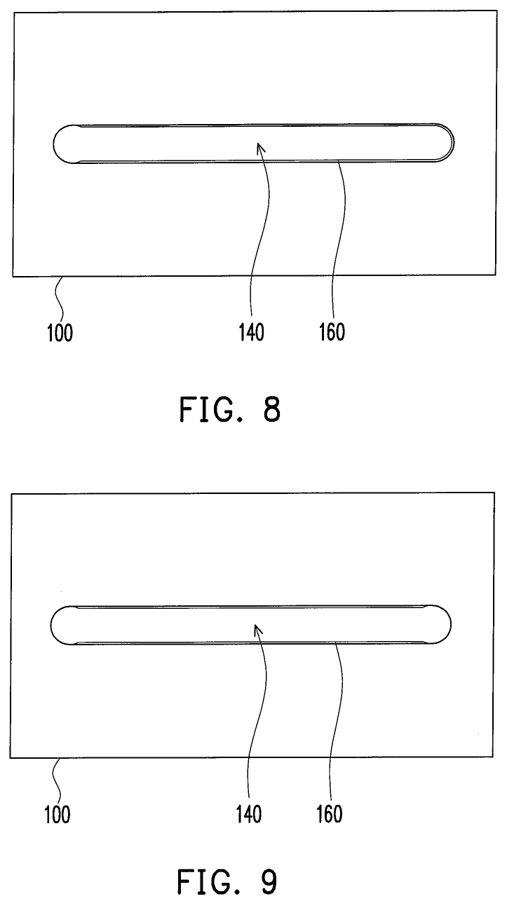

FIG. 8 illustrates another alternative process of forming the third metallic layer of FIG. 5, and FIGS. 8 and 9 illustrate another alternative process of forming a fifth metallic layer of FIG. 6. Referring to FIG. 8, after forming the plating seed layer 160 as shown in FIG. 3, the method may alternatively includes: removing a part of the plating seed layer 160 on wall of the strip shaped through hole 140; and then forming the third metallic layer 152 as shown in FIG. 5 by a plating process with the rest plating seed layer 160. The plating seed layer 160 of the part of wall of the strip shaped through hole 140 for example can be removed by using the drill needle D10 used for forming the strip shaped through hole 140, or other tools or other processes. Referring to FIG. 9, after removing the plating seed layer 160 on the wall of an end of the strip shaped through hole 140, the method may further include removing the plating seed layer 160 on the wall of another end of the strip shaped through hole 140. After that, the fifth metallic layer 154 is formed by plating with the plating seed layer 160.

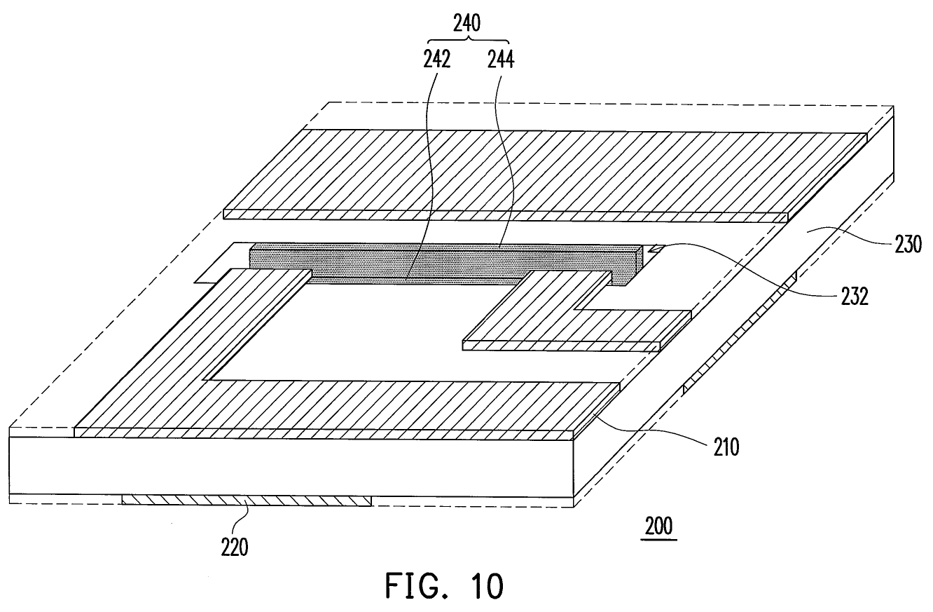

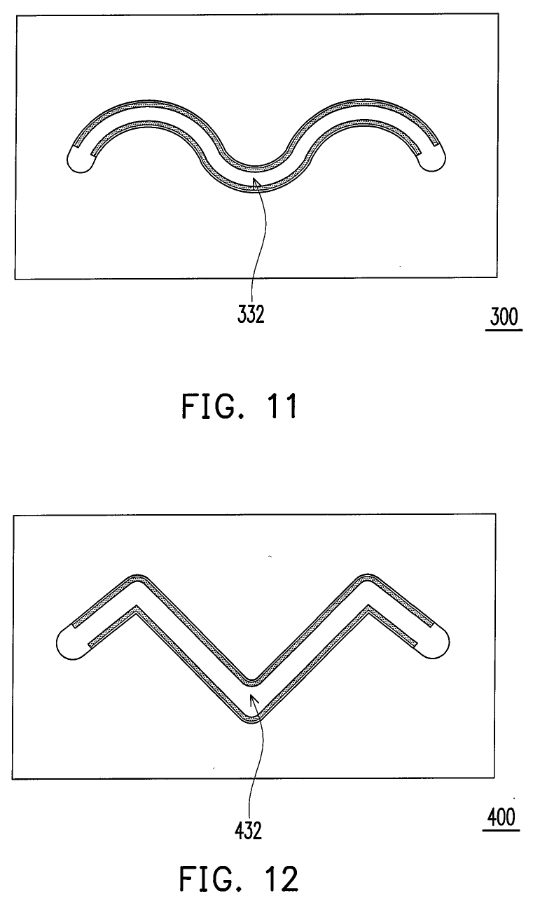

FIG. 10 is a perspective view illustrating a circuit substrate according to an embodiment of the present invention. FIGS. 11 and 12 are top views of circuit substrates of another two embodiments of the present invention. The proportions exhibited therein are for illustration purpose only and are not to limit the present invention. Referring to FIG. 10, a circuit substrate 200 of the embodiment according to the present invention includes a first circuit layer 210, a second circuit layer 220, a dielectric layer 230 and a metallic layer 240. The dielectric layer 230 is disposed between the first circuit layer 210 and the second circuit layer 220, and has a strip shaped through hole 232 configured therethrough. The metallic layer 240 is disposed on a part of a wall of the strip shaped through hole 232, and is electrically connected with the first circuit layer 210 and/or the second circuit layer 220. The metallic layer 240 functions as a passive layer hereby. The circuit substrate 200 of the current embodiment can be fabricated by referring to the method for fabricating the passive circuit in the circuit substrate of the foregoing embodiments.

In the embodiment, the metallic layer 240 includes a first electrode plate 242 and a second electrode plate 244, isolated one from another and functioning as a capacitance circuit. Two ends of the first electrode plate 242 for example are electrically connected to the first circuit layer 210, and two ends of the second electrode plate 244 for example are electrically connected to the second circuit layer 220. In other embodiment, electrically connection layout of the two ends of the first electrode plate 242, the two ends of the second electrode plate 244 with the first circuit layer 210, and the second circuit layer 220 can be alternatively modified. Further, the metallic layer 240 can also be a continuous metallic layer functioning as a resistant circuit. The circuit substrate 200 may further include a dielectric filling material filled in the strip shaped through hole 232. For convenience of illustrating the foregoing parts of the circuit substrate 200, the dielectric filling material is not shown in FIG. 10, while it can be understood by referring to the dielectric filling material 170 as shown in FIG. 7.

In this embodiment, the strip shaped through hole 200 is configured as a straight line form. In other embodiment, such as that shown in FIG. 11, the strip shaped through hole 300 is configured as an “S” form; and such as that shown in FIG. 12, the strip shaped through hole 400 is configured as or a sawtooth form. The form of the strip shaped through hole may be modified according to practical condition.

In summary, the circuit substrate and the method for fabricating a passive circuit in the circuit substrate according to the present invention are featured as forming a metallic layer on a wall of a strip shaped through hole of the circuit substrate, and forming the passive circuit in facilitation with the metallic layer. The circuit substrate and the method for fabricating a passive circuit in the circuit substrate according to the present invention are compatible with conventional processing in the art. As such the present invention has the advantages in saving production time and costs. Further, the passive circuit layout of the circuit substrate according to the present invention is non-horizontally disposed, the layout can be handled relatively easy so as to improve the utility of the present invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a passive circuit in a circuit substrate, comprising:
providing the circuit substrate, the circuit substrate comprising a first metallic layer, a second metallic layer, and a dielectric layer, the dielectric layer being disposed between the first metallic layer and the second metallic layer;
forming a strip shaped through hole through the circuit substrate; and
forming a third metallic layer on a part of a wall of the strip shaped through hole, the third metallic layer being electrically connected to the first metallic layer and/or the second metallic layer, and the third metallic layer functioning as the passive circuit.

2. The method for fabricating a passive circuit in a circuit substrate according to claim 1, wherein the step of forming the third metallic layer comprises:
forming a plating seed layer on the entire wall of the strip shaped through hole, wherein the plating seed layer is electrically connected to the first metallic layer and/or the second metallic layer;
removing a part of the plating seed layer from the wall of the strip shaped through hole; and
forming the third metallic layer by plating with the rest plating seed layer.

3. The method for fabricating a passive circuit in a circuit substrate according to claim 2, wherein the step of forming a strip shaped through hole and the step of removing a part of the plating seed layer from the wall of the strip shaped through hole are conducted by using a same drill needle.

4. The method for fabricating a passive circuit in a circuit substrate according to claim 2, wherein the step of removing a part of the plating seed layer from the wall of the strip shaped through hole comprises:
removing the plating seed layer from the wall of an end of the strip shaped through hole.

5. The method for fabricating a passive circuit in a circuit substrate according to claim 4, wherein the step of removing a part of the plating seed layer from the wall of the strip shaped through hole further comprises:
removing the plating seed layer from the wall of another end of the strip shaped through hole.

6. The method for fabricating a passive circuit in a circuit substrate according to claim 1, wherein the step of forming the third metallic layer comprises:
forming a plating seed layer on an entire wall of the striped shaped through hole, the plating seed layer being electrically connected with the first metallic layer and/or the second metallic layer;
forming a fourth metallic layer by a plating process with the plating seed layer; and
removing a part of the fourth metallic layer and the plating seed layer from the wall of the strip shaped through hole so as to form the third metallic layer.

7. The method for fabricating a passive circuit in a circuit substrate according to claim 6, wherein the step of forming a strip shaped through hole and the step of removing a part of the fourth metallic layer from the wall of the strip shaped through hole are conducted by using a same drill needle.

8. The method for fabricating a passive circuit in a circuit substrate according to claim 6, wherein the step of removing a part of the fourth metallic layer from the wall of the strip shaped through hole comprises:
removing the fourth metallic layer from the wall of an end of the strip shaped through hole.

9. The method for fabricating a passive circuit in a circuit substrate according to claim 8, wherein the step of removing a part of the fourth metallic layer from the wall of the strip shaped through hole further comprises:
removing the fourth metallic layer from the wall of another end of the strip shaped through hole.

10. The method for fabricating a passive circuit in a circuit substrate according to claim 1, further comprising:
filling a dielectric filling material into the strip shaped through hole after forming the third metallic layer.

11. The method for fabricating a passive circuit in a circuit substrate according to claim 1, further comprising:
patterning the first metallic layer and the second metallic layer, to form a first circuit layer and a second circuit layer, respectively.
